(19) United States
(12) Patent Application Publication
(10) Pub. No.: US 2019/0296139 A1
(43) Pub. Date: Sep. 26, 2019

(54) Transistor and Method for Manufacturing the Same

(71) Applicant: Innoscience (Zhuhai) Technology Co., Ltd., Zhuhai (CN)

(72) Inventors: Jin Wei, Zhuhai (CN); Junyoun Kim, Zhuhai (CN)

(21) Appl. No.: 16/360,535

(22) Filed: Mar. 21, 2019

(30) Foreign Application Priority Data
Mar. 26, 2018 (CN) 201810251454.4

(51) Int. Cl. H01L 29/778; H01L 29/20; H01L 29/205; H01L 29/66; H01L 21/265

(52) U.S. Cl. CPC H01L 29/7786; H01L 29/2003; H01L 21/2654; H01L 29/66462; H01L 29/205

(57) ABSTRACT

The present application provides a transistor and a manufacturing method thereof, and can at least partially solve the problem of degraded characteristics and deteriorated reliability with use of existing transistors with a P-cap layer. The transistor includes: a channel layer and a barrier layer stacked on top of each other; and a source, a drain, and a gate spaced apart from one another on a side of the barrier layer distal to the channel layer. The gate is between the source and the drain, a P-cap layer is provided between the barrier layer and the gate, and a Schottky contact is formed between the P-cap layer and the gate. Two side edge regions of the P-cap layer respectively close to the source and the drain are two electric field modulation regions spaced apart from each other and capable of inducing positive charges under a positive gate-source voltage.

### CROSS-REFERENCE TO RELATED APPLICATION

This application claims priority to Chinese Patent Application No. 201810251454.4 filed Mar. 26, 2018, the disclosure of which is hereby incorporated by reference in its entirety.

### TECHNICAL FIELD

The present disclosure belongs to the technical field of transistors (especially GaN transistors), and in particular relates to a transistor and a manufacturing method thereof.

### BACKGROUND

Gallium nitride (GaN) semiconductors have characteristics such as large band gap, high breakdown voltage, high electron saturation velocity, high drift velocity, etc. Therefore, a gallium nitride transistor fabricated using a GaN semiconductor has advantages such as high breakdown voltage, low on resistance, fast response speed, and the like, and is thus especially suited to serve as a switching element.

As shown in FIG. 1, in order to improve performance of a GaN transistor, the GaN transistor is formed as an Enhancement-mode GaN high electron mobility transistor (E-mode GaN HEMT), with a P-cap 3 being inserted between a gate 23 and a barrier layer 12 thereof. However, for such GaN transistor, when a positive gate-source voltage reaches a certain value, a PN junction between the P-cap layer 3 and a channel is turned on, resulting in a large gate current. To avoid this problem, a Schottky contact may be formed between the gate 23 and the P-cap layer 3, i.e., a Schottky junction is formed, and therefore, when a positive gate-source voltage is applied, the Schottky junction may withstand a part of the voltage, which increases an allowable range of a gate voltage and avoids a large gate current.

However, when a positive gate-source voltage is applied, the Schottky junction between the gate 23 and the P-cap layer 3 may be subjected to a reverse bias voltage and generate an electric field at the Schottky junction, and intensities of the electric field at two edge areas (i.e., areas enclosed by dotted lines in the drawing) of the Schottky junction respectively close to a source and a drain are much greater than that at the center region. Thus, the high electric field at the edges of the Schottky junction may degrade characteristics of the device and deteriorate reliability of the device during long term operation.

### SUMMARY

The present disclosure at least partially solves the problem that an existing transistor provided with a P-cap layer may have degraded characteristics and deteriorated reliability with use, and provides a transistor whose characteristics can be avoided from being degraded and whose reliability is good.

In one aspect, the present disclosure provides a transistor, including:

a channel layer and a barrier layer stacked on top of each other;

a source, a drain, and a gate provided spaced apart from one another on a side of the barrier layer distal to the channel layer, wherein the gate is between the source and the drain, a P-cap layer is provided between the barrier layer and the gate, and a Schottky contact is formed between the P-cap layer and the gate; and

two side edge regions of the P-cap layer respectively close to the source and the drain are two electric field modulation regions spaced apart from each other, and the electric field modulation regions are capable of inducing positive charges under a positive gate-source voltage.

Optionally, the electric field modulation regions are high resistance zones formed by doping the two side edge regions of the P-cap layer respectively close to the source and the drain with a doping element.

Further optionally, the doping element includes any one or more of argon, fluorine, nitrogen, oxygen, silicon, iron, carbon, and boron.

Optionally, the P-cap layer has a thickness of 20 nm to 1000 nm; and

each of the electric field modulation regions extends downward from a surface of the P-cap layer close to the gate by an extending distance less than or equal to the thickness of the P-cap layer.

Optionally, of the two electric field modulation regions, one close to the source is a first electric field modulation region, and the other close to the drain is a second electric field modulation region; an edge of the first electric field modulation region close to the source is an edge of the P-cap layer close to the source, an edge of the first electric field modulation region distal to the source is between a first limit and a second limit, the first limit is 400 nm away from a first edge line and at a side of the first edge line close to the source, and the second limit is 500 nm away from the first edge line and at a side of the first edge line distal to the source, the first edge line being an edge line, close to the source, of a contacting area between the gate and the P-cap layer; and

an edge of the second electric field modulation region close to the drain is an edge of the P-cap layer close to the drain, an edge of the second electric field modulation region distal to the drain is between a third limit and a fourth limit, the third limit is 400 nm away from a second edge line and at a side of the second edge line close to the drain, and the fourth limit is 500 nm away from the second edge line and at a side of the second edge line distal to the drain, the second edge line being an edge line, close to the drain, of the contacting area between the gate and the P-cap layer.

Optionally, the transistor is a gallium nitride transistor.

Optionally, the transistor further includes:

a substrate, wherein the channel layer is closer to the substrate than the barrier layer.

In another aspect, the present disclosure provides a method for manufacturing the above transistor, which includes:

a step of forming the channel layer and the barrier layer, a step of forming the P-cap layer having the electric field modulation regions, and a step of forming the source, the drain, and the gate.

Optionally, the step of forming the P-cap layer having the electric field modulation regions includes:

forming a P-type semiconductor material layer, doping two regions of the P-type semiconductor material layer spaced apart from each other to form high resistance zones by ion implantation, and then etching the P-type semiconductor material layer such that the remaining P-type semiconductor material layer forms the P-cap layer and the remaining high resistance zones form the electric field modulation regions;

or,

forming the P-cap layer, and doping the two side edge regions of the P-cap layer respectively close to the source and the drain to form high resistance zones by ion implantation, the high resistance zones being electric field modulation regions.

Optionally, the step of forming the channel layer and the barrier layer includes:

forming the channel layer and the barrier layer by epitaxial growth, respectively.

In the transistor of the present disclosure, an electric field modulation region is provided at an edge of the gate (that is, at an edge of the Schottky junction), and the electric field modulation regions can induce extra positive charges at a positive gate-source voltage, so that electric lines of force meant to be connected between the gate and edge areas of the P-cap layer may be partially cut off in the electric field modulation regions, which reduces the actual electric field intensity at the edge of the Schottky junction, thereby avoiding characteristics of the device from being degraded and improving reliability of the device.

### BRIEF DESCRIPTION OF THE DRAWINGS

FIG. 1 is a schematic cross-sectional view of a structure of a conventional transistor;

FIG. 2 is a schematic cross-sectional view of a structure of a transistor according to an embodiment of the present disclosure;

FIG. 3 is a partially enlarged cross-sectional view of a P-cap layer of a transistor according to an embodiment of the present disclosure;

FIG. 4 is a partially enlarged cross-sectional view of a P-cap layer of another transistor according to an embodiment of the present disclosure;

FIG. 5 is a schematic cross-sectional view of a structure after forming a P-type semiconductor material layer in a method for manufacturing a transistor according to an embodiment of the present disclosure;

FIG. 6 is a schematic cross-sectional view of a structure after forming a high resistance zone in a P-type semiconductor material layer in a method for manufacturing a transistor according to an embodiment of the present disclosure; and

FIG. 7 is a schematic cross-sectional view of a structure after forming a P-cap layer in a method for manufacturing a transistor according to an embodiment of the present disclosure.

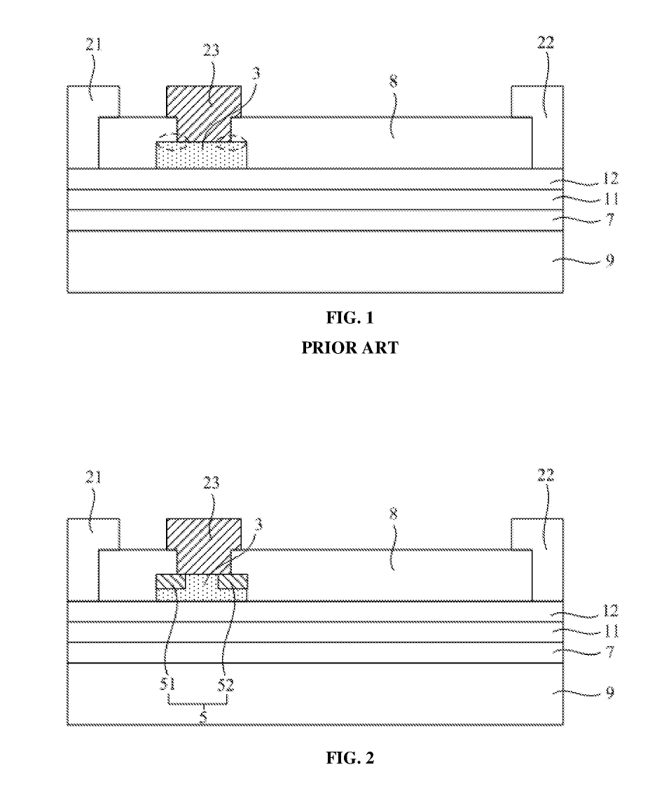

Reference Numerals: 11: channel layer; 12: barrier layer; 21: source; 22: drain; 23: gate; 3: P-cap layer; 39: P-type semiconductor material layer; 5: electric field modulation region; 51: first electric field modulation region; 52: second electric field modulation region; 59: high resistance zone; 7: transition layer; 8: insulating layer; 9: substrate.

### DETAILED DESCRIPTION

To enable those skilled in the art to better understand technical solutions of the present disclosure, the present disclosure will be described in detail below in conjunction with the accompanying drawings and specific implementations.

As shown in FIGS. 2 to 7, the embodiment provides a transistor, which includes: a channel layer 11 and a barrier layer 12 stacked on top of each other; a source 21, a drain 22 and a gate 23 spaced apart from one another at a side of the barrier layer 12 distal to the channel layer 11, wherein the gate 23 is between the source 21 and the drain 22, a P-cap layer 3 is provided between the gate 23 and the barrier layer 12, and a Schottky contact is formed between the P-cap layer 3 and the gate 23.

As shown in FIG. 2, the transistor in the embodiment includes the channel layer 11 and the barrier layer 12 stacked on top of each other, a heterojunction is formed between the channel layer 11 and the barrier layer 12, and the barrier layer 12 has larger band gap than the channel layer 11, so that two-dimensional electron gas (2DEG) may be formed at a side of the heterojunction boundary close to the channel layer 11. The source 21, the drain 22, the gate 23 are provided at a side of the barrier layer 12 distal to the channel layer 11, the source 21 and the drain 22 are in direct contact with the barrier layer 12, the gate 23 is located between the source 21 and the drain 22, the P-cap layer 3 is provided between the gate 23 and the barrier layer 12, and the P-cap layer 3 is made of a P-type doped semiconductor material and configured to deplete the 2DEG in a channel under the gate 23. Moreover, a Schottky contact (or a Schottky junction) is formed between the P-cap layer 3 and the gate 23, so that when a positive gate-source voltage is applied, the Schottky junction can withstand a part of the voltage, thereby increasing allowable range of a gate voltage, and avoiding a large gate current.

Specifically, as shown in FIG. 2, an insulating layer 8 may further be provided on the side of the barrier layer 12 distal to the channel layer 11. The source 21, the drain 22, and the gate 23 may contact with the barrier layer 12 or the P-cap layer 3 through via holes in the insulating layer 8.

In an embodiment, the transistor further includes a substrate 9, and the channel layer 11 is closer to the substrate 9 than the barrier layer 12.

That is, the barrier layer 12 may be farther from the substrate 9 than the channel layer 11, and then the source 21, the drain 22, and the gate 23 are located on a side of the barrier layer 12 distal to the substrate 9.

In an embodiment, the transistor further includes a transition layer 7 provided between the substrate 9 and the channel layer 11.

Since the barrier layer 12, the channel layer 11, and the like are usually prepared by epitaxial growth, and lattice parameters or the like of materials of these layers may not match with that of a material of the substrate 9, a transition layer 7, which adjusts stress in the crystal growth process, may be provided between the substrate 9 and the channel layer 11, so that a high-quality channel layer 11 can be grown on the transition layer 7.

In an embodiment, the transistor is a GaN transistor.

For example, in a GaN transistor, the substrate 9 may be made of a material selected from any one of silicon (Si), sapphire, aluminum nitride (AlN), gallium nitride (GaN), silicon carbide (SiC), and the like; the transition layer 7 may be made of a material including any one or more of gallium nitride (GaN), aluminum nitride (AlN), and aluminum gallium nitride (AlGaN); the channel layer 11 may be made of a material selected from any one of gallium nitride (GaN), aluminum gallium nitride (AlGaN), indium gallium nitride (InGaN), aluminum indium gallium nitride (AlInGaN) and indium aluminum nitride (AlInN); the barrier layer 12 may be made of a material including any one or more of gallium nitride (GaN), aluminum gallium nitride (AlGaN), indium gallium nitride (InGaN), aluminum indium gallium nitride (AlInGaN), and indium aluminum nitride (AlInN), wherein at least one material in the barrier layer 12 have a band gap greater than a band gap of the material of the channel layer 11; and the P-cap layer 3 may be made of a material including any one or more of P-type doped gallium nitride (GaN), P-type doped aluminum gallium nitride (AlGaN), P-type doped indium gallium nitride (InGaN), P-type doped aluminum indium gallium nitride (AlInGaN), and P-type doped aluminum indium nitride (AlInN).

Needless to say, the specific structure, material, and the like of the transistor of this embodiment are not limited thereto. For example, the insulating layer 8 may be absent at the side of the barrier layer 12 distal to the channel layer 11, and the source 21, the drain 22, and the gate 23 may be in direct contact with the barrier layer 12 or the P-cap layer 3. For another example, the source 21 and the drain 22 may be in direct contact with the channel layer 11. For another example, the barrier layer 12, the channel layer 11, and other layer(s) of the transistor may also be made of other known materials.

In the transistor of the embodiment, the two side edge regions of the P-cap layer 3 respectively close to the source 21 and the drain 22 are two electric field modulation regions 5 spaced apart from each other. The electric field modulation regions 5 are able to induce positive charges at a positive gate-source voltage.

As shown in FIG. 2, the two side edges of the P-cap layer 3 of the transistor of the embodiment close to the source 21 and the drain 22 are both electric field modulation regions 5, and the electric field modulation region 5 refers to a region able to induce positive charges under the positive gate-source voltage.

In an existing transistor, when a positive gate-source voltage is applied, a certain number of positive charges are induced in the gate 23, and a certain number of negative charges are induced in the P-cap layer 3, thereby forming an electric field therebetween. Due to electric field edge-crowding effect, intensity of the electric field at an edge of the Schottky junction (i.e., edges of the gate 23 respectively closer to the source 21 and the drain 22) is greater, which is likely to render the device with degraded characteristics and deteriorated reliability.

In the transistor of the embodiment, the electric field modulation regions 5 are provided at the edges of the gate 23 (i.e., at the edge of the Schottky junction), and the electric field modulation regions 5 can induce extra positive charges at a positive gate-source voltage, so that electric lines of force meant to be connected between the gate 23 and edge areas of the P-cap layer 3 may be partially cut off in the electric field modulation regions 5, which reduces the actual electric field intensity at the edge of the Schottky junction, thereby avoiding characteristics of the device from being degraded and improving reliability of the device.

In an embodiment, each of the electric field modulation regions 5 is a high resistance zone formed by doping the two side edge regions of the P-cap layer 3 close to the source 21 and the drain 22 with a doping element. In an embodiment, the doping element includes any one or more of argon (Ar), fluorine (F), nitrogen (N), oxygen (O), silicon (Si), iron (Fe), carbon (C), and boron (B).

That is, the P-cap layer 3 may be doped with one or more of the above-mentioned materials that are generally used for forming a high resistance zone, and the doped high resistance zone is the electric field modulation region 5.

In an embodiment, the P-cap layer 3 has a thickness in the range of 20 nm to 1000 nm; the electric field modulation region 5 extends downward from a surface of the P-cap layer 3 close to the gate 23, and an extending depth is less than or equal to the thickness of the P-cap layer 3.

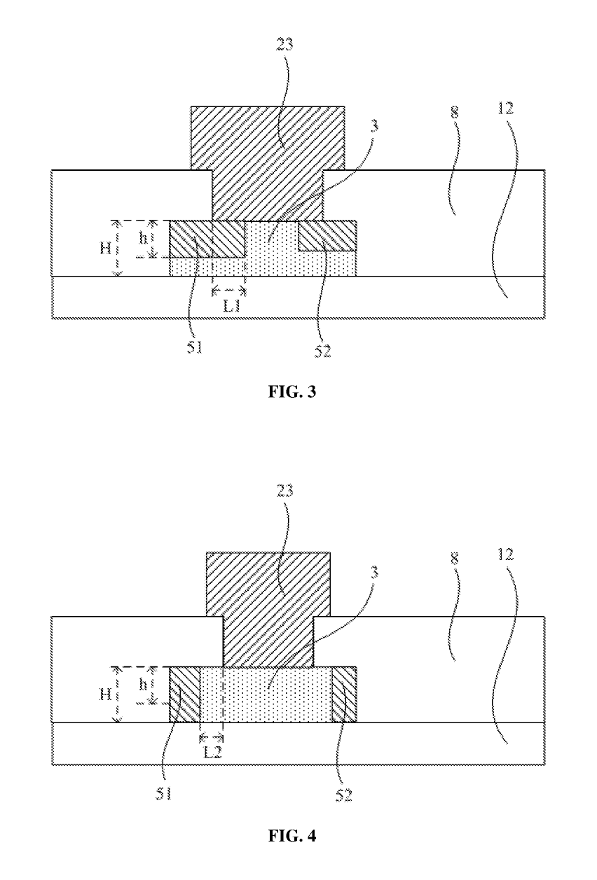

As shown in FIGS. 3 and 4, the thickness H of the entire P-cap layer 3 preferably satisfies: 20 nm≤H≤1000 nm. Moreover, the electric field modulation region 5 is at least located at the surface of the P-cap layer 3 close to the gate 23, and extends from the surface to the inside of the P-cap layer 3 by a certain depth. The depth h may have a maximum value equal to the thickness of the P-cap layer 3, that is, 0 nm<h≤H. That is, in a thickness direction of the P-cap layer 3, the electric field modulation region 5 necessarily extends from the surface of the P-cap layer 3 close to the gate 23 to a side of the P-cap layer 3 distal to the gate 23, and the electric field modulation region 5 may extend into only a portion of the P-cap layer 3, as shown in FIGS. 2 and 3, or may penetrate through the P-cap layer 3, as shown in FIG. 4.

In an embodiment, of the two electric field modulation regions 5, one close to the source 21 is a first electric field modulation region 51, and the other close to the drain 22 is a second electric field modulation region 52.

An edge of the first electric field modulation region 51 close to the source 21 is the edge of the P-cap layer 3 close to the source 21, and an edge of the first electric field modulation region 51 distal to the source 21 is between a first limit and a second limit. The first limit is at a side of a first edge line close to the source 21 with a distance of 400 nm from the first edge line, the second limit is at a side of the first edge line distal to the source 21 with a distance of 500 nm from the first edge line, and the first edge line is an edge line, close to the source 21, of a contacting area between the gate 23 and the P-cap layer 3.

An edge of the second electric field modulation region 52 close to the drain 22 is the edge of the P-cap layer 3 close to the drain 22, and an edge of the second electric field modulation region 52 distal to the drain 22 is between a third limit and a fourth limit. The third limit is at a side of a second edge line close to the drain 22 with a distance of 400 nm from the second edge line, the fourth limit is at a side of the second edge line distal to the drain 22 with a distance of 500 nm from the second edge line, and the second edge line is an edge line, close to the drain 22, of the contacting area between the gate 23 and the P-cap layer 3.

That is, the two electric field modulation regions 5 in the P-cap layer 3 may be referred to as the first electric field modulation region 51 and the second electric field modulation region 52, respectively. Hereinafter, a preferred size range of the electric field modulation region 5 is described by taking the first electric field modulation region 51 close to the source 21 as an example.

As shown in FIGS. 2 to 4, the edge of the first electric field modulation region 51 close to the source 21 (i.e., the left edge of the first electric field modulation region 51 in the figure) is the edge of the P-cap layer 3 close to the source 21. That is, the first electric field modulation region 51 may extend to the edge of the P-cap layer 3 close to the source 21.

It can be seen that the gate 23 and the P-cap layer 3 necessarily have a contacting area, and position of an edge at the side of the first electric field modulation region 51 distal to the source 21 (i.e., the right edge of the first electric field modulation region 51 in the figure) is defined as follows.

Here, an edge of the contacting area close to the source 21 (the left boundary of L1 in FIG. 3 or the right boundary of L2 in FIG. 4) is the first edge line. As shown in FIG. 3, the edge of the first electric field modulation region 51 distal to the source 21 (i.e., the right edge of the first electric field modulation region 51 in the figure) may be farther from the source 21 than the first edge line (i.e., on the right side of the first edge line) by a distance having a maximum value of 500 nm, i.e., L1 in FIG. 3 has a maximum value of 500 nm. Alternatively, as shown in FIG. 4, the edge of the first electric field modulation region 51 away from the source 21 (i.e., the right edge of the first electric field modulation region 51 in the figure) may be closer to the source 21 than the first edge line (i.e., on the left side of the first edge line) by a distance having a maximum value of 400 nm, i.e., L2 in FIG. 4 has a maximum value of 400 nm.

As such, the edge of the first electric field modulation region 51 distal to the source 21 (the right edge of the first electric field modulation region 51 in the figure) should be between the two boundaries of L1 and L2 when L1=500 nm and L2=400 nm.

Needless to say, in a case where the edge of the first electric field modulation region 51 distal to the source 21 is farther from the source 21 than the edge of the contacting area (i.e., the case shown in FIG. 3), the first electric field modulation region 51 cannot contact with the second electric field modulation region 52; in a case where the edge of the first electric field modulation region 51 distal to the source 21 is closer to the source 21 than the edge of the contacting area (i.e., the case shown in FIG. 4), the P-cap layer 3 necessarily has a portion that is closer to the source 21 than the contacting area but not the first electric field modulation region (i.e., the portion left to the right boundary of L2 in FIG. 4), which will not be described in detail herein.

Needless to say, it should be understood that the limitations of preferred position and size of the second electric field modulation region 52 in the P-cap layer 3 correspond to those of the first electric field modulation region 51, and the only difference therebetween is that the source 21 is replaced with the drain 22, and therefore detailed description is omitted herein.

Needless to say, it should be understood that although the preferred position and size range are the same, this does not mean that in each transistor, the sizes of the first electric field modulation region 51 and the second electric field modulation region 52 are the same, i.e., forms of the two electric field modulation regions are not required to be the same.

The P-cap layer 3 and the electric field modulation region 5 that meet the above size requirements can not only achieve the basic functions of the transistor but also achieve a good effect of reducing electric field at the edge of the Schottky junction, and thus are preferable.

The embodiment also provides a method for manufacturing the above transistor, which includes:

a step of forming the channel layer 11 and the barrier layer 12, a step of forming the P-cap layer 3 having the electric field modulation region 5, and a step of forming the source 21, the drain 22, and the gate 23.

That is, the structures may be separately formed, so as to obtain the transistor. Needless to say, it should be understood that an order of forming the structures may be different depending on form of the transistor and a specific manufacturing process, and therefore, the literal order of the above steps does not limit the order of forming the respective structures.

Specifically, the method for manufacturing the transistor may include the following steps.

In S101, the substrate 9 is provided.

That is, the substrate 9 is provided as a base of other structures of the transistor.

Specifically, the substrate 9 may be made of a material selected from any one of silicon (Si), sapphire, aluminum nitride (AlN), gallium nitride (GaN), silicon carbide (SiC), and the like.

In S102, optionally, the transition layer 7 is formed.

In order to better match the material of the substrate 9 with materials of the channel layer 11 and the barrier layer 12, a transition layer 7 for transition and buffer may be firstly formed on the substrate 9, and the transition layer 7 may be formed by epitaxial growth.

Specifically, the transition layer 7 may be made of a material including any one or more of gallium nitride (GaN), aluminum nitride (AlN), aluminum gallium nitride (AlGaN).

In S103, the channel layer 11 and the barrier layer 12 are formed.

That is, the channel layer 11 and the barrier layer 12 are formed sequentially.

The channel layer 11 is formed first, the barrier layer 12 is then formed, and subsequently, the P-cap layer 3 is formed.

In an embodiment, in this step, the channel layer 11 and the barrier layer 12 are formed separately by epitaxial growth.

That is, the above channel layer 11 and barrier layer 12 may be separately formed by an epitaxial growth process.

Specifically, the channel layer 11 may be made of a material including any one of gallium nitride (GaN), aluminum gallium nitride (AlGaN), indium gallium nitride (InGaN), aluminum indium gallium nitride (AlInGaN) and indium aluminum nitride (AlInN); the barrier layer 12 may be made of a material including any one or more of gallium nitride (GaN), aluminum gallium nitride (AlGaN), indium gallium nitride (InGaN), aluminum indium gallium nitride (AlInGaN), and indium aluminum nitride (AlInN), and at least one material in the barrier layer 12 have a band gap greater than a band gap of the material of the channel layer 11.

In S104, optionally, as an implementation of the embodiment, a P-type semiconductor material layer 39 is formed, and two regions of the P-type semiconductor material layer 39 spaced apart from each other are respectively doped to form high resistance zones 59 by ion implantation, and then the P-type semiconductor material layer 39 is etched such that the remaining P-type semiconductor material layer 39 forms the P-cap layer 3 and the remaining high resistance zones 59 form the electric field modulation regions 5.

An “etching process” herein includes steps of forming a material layer, coating a photoresist, exposing, developing, etching, removing the photoresist, and the like, which will not be described in detail herein.

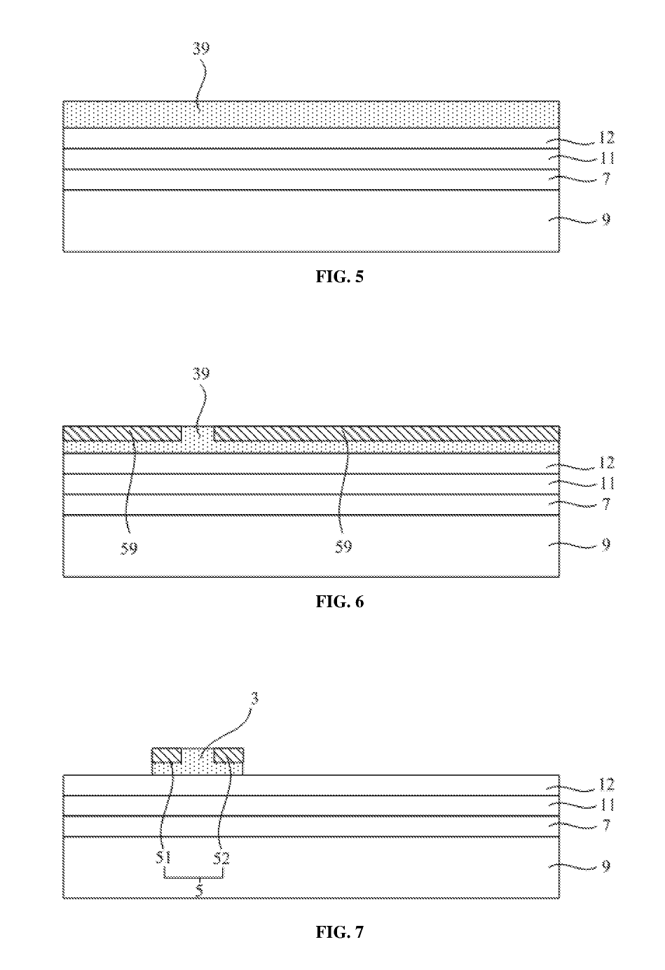

That is, a complete P-type semiconductor material layer 39 may be formed first, obtaining the structure shown in FIG. 5. Then, ion implantation is performed on at least regions corresponding to the electric field modulation regions 5 in the layer so that the implanted regions form high resistance zones 59, obtaining the structure shown in FIG. 6. Finally, undesired portion of the P-type semiconductor material layer 39 is etched off, and the remaining portion naturally becomes the P-cap layer 3 having the electric field modulation regions 5, obtaining the structure shown in FIG. 7.

According to the above method, as shown in FIG. 6, regions to be removed in the P-type semiconductor material layer 39 may also be ion-implanted because the P-type semiconductor material layer 39 exists in these regions, thus the implanted ions will not affect the barrier layer 12 and the like under the P-type semiconductor material layer 39, and because the P-type semiconductor material layer 39 in these regions is finally removed, the structure of the transistor is not affected regardless of whether or not the P-type semiconductor material layer 39 in these regions is doped. Therefore, according to the above process, even if there is a certain deviation in alignment during the ion implantation, the barrier layer 12 and the like will not be affected, and the process has high reliability.

Specifically, ions implanted in the ion implantation are ions generally used for forming a high resistance zone in a P-type semiconductor material layer, and may include any one or more of argon (Ar), fluorine (F), nitrogen (N), oxygen (0), silicon (Si), iron (Fe), carbon (C), boron (B), and the like.

Alternatively, as another implementation of the embodiment, this step may also include: forming a P-cap layer 3, and doping two side edge regions of the P-cap layer 3 respectively close to the source 21 and the drain 22 by ion implantation to form high resistance zones, and the high resistance zones being the electric field modulation regions 5.

That is, the P-type semiconductor material layer 39 may be etched first to form the P-cap layer 3, and then the corresponding regions of the P-cap layer 3 may be ion-implanted to form the electric field modulation regions 5.

In S105, the insulating layer 8, the source 21, the drain 22, and the gate 23 are formed.

That is, the insulating layer 8, the source 21, the drain 22, the gate 23, and other structures are formed according to conventional processes to obtain the transistor shown in FIG. 2, and the manufacturing is completed.

It could be understood that the above implementations are merely exemplary implementations for illustrating the principle of the present disclosure, but the present disclosure is not limited thereto. For a person of ordinary skill in the art, various variations and improvements may be made without departing from the spirit and essence of the present disclosure, and these variations and improvements are also considered to be within the protection scope of the present disclosure.

1. A transistor, comprising:
a channel layer and a barrier layer stacked on top of each other; and
a source, a drain, and a gate spaced apart from one another on a side of the barrier layer distal to the channel layer, wherein the gate is between the source and the drain, a P-cap layer is provided between the barrier layer and the gate, and a Schottky contact is formed between the P-cap layer and the gate,
wherein two side edge regions of the P-cap layer respectively close to the source and the drain are two electric field modulation regions spaced apart from each other, and the electric field modulation regions are capable of inducing positive charges under a positive gate-source voltage.

2. The transistor of claim 1, wherein
the electric field modulation regions are high resistance zones formed by doping two side edge regions of the P-cap layer respectively close to the source and the drain with a doping element.

3. The transistor of claim 3, wherein
the doping element comprises any one or more of argon, fluorine, nitrogen, oxygen, silicon, iron, carbon, and boron.

4. The transistor of claim 1, wherein
the P-cap layer has a thickness of 20 nm to 1000 nm, and
each of the electric field modulation regions extends downward from a surface of the P-cap layer close to the gate by an extending distance less than or equal to the thickness of the P-cap layer.

5. The transistor of claim 1, wherein
of the two electric field modulation regions, one close to the source is a first electric field modulation region, and the other close to the drain is a second electric field modulation region,
an edge of the first electric field modulation region close to the source is an edge of the P-cap layer close to the source, an edge of the first electric field modulation region distal to the source is between a first limit and a second limit, the first limit is 400 nm away from a first edge line and at a side of the first edge line close to the source, and the second limit is 500 nm away from the first edge line and at a side of the first edge line distal to the source, the first edge line being an edge line, close to the source, of a contacting area between the gate and the P-cap layer, and
an edge of the second electric field modulation region close to the drain is an edge of the P-cap layer close to the drain, an edge of the second electric field modulation region distal to the drain is between a third limit and a fourth limit, the third limit is 400 nm away from a second edge line and at a side of the second edge line close to the drain, and the fourth limit is 500 nm away from the second edge line and at a side of the second edge line distal to the drain, the second edge line being an edge line, close to the drain, of the contacting area between the gate and the P-cap layer.

6. The transistor of claim 1, wherein
the transistor is a gallium nitride transistor.

7. The transistor of claim 1, further comprising:
a substrate, wherein the channel layer is closer to the substrate than the barrier layer.

8. A method for manufacturing a transistor, wherein the transistor is the transistor of claim 1, and the method comprises:
a step of forming the channel layer and the barrier layer, a step of forming the P-cap layer having the electric field modulation regions, and a step of forming the source, the drain, and the gate.

9. The method of claim 8, wherein the step of forming the P-cap layer having the electric field modulation regions comprises:
forming a P-type semiconductor material layer, doping two regions of the P-type semiconductor material layer spaced apart from each other to form high resistance zones by ion implantation, and then etching the P-type semiconductor material layer such that the remaining P-type semiconductor material layer forms the P-cap layer and the remaining high resistance zones form the electric field modulation regions.

10. The method of claim 8, wherein the step of forming the channel layer and the barrier layer comprises:
forming the channel layer and the barrier layer by epitaxial growth, respectively.

11. The method of claim 8, wherein the step of forming the P-cap layer having the electric field modulation regions comprises:
forming the P-cap layer, and doping the two side edge regions of the P-cap layer respectively close to the source and drain to form high resistance zones by ion implantation, the high resistance zones being electric field modulation regions.
